(19) United States
(12) Patent Application Publication
(10) Pub. No.: US 2026/0096131 A1
(43) Pub. Date: Apr. 2, 2026

(54) SEMICONDUCTOR DEVICE

(71) Applicant: KABUSHIKI KAISHA TOSHIBA, Tokyo (JP)

(72) Inventors: Ryoma KANEKO, Ota (JP); Seiya TAKEDA, Yokohama (JP); Jumpei TAJIMA, Mitaka (JP); Shinya NUNOUE, Ichikawa (JP); Toshiki HIKOSAKA, Kawasaki (JP)

(73) Assignee: KABUSHIKI KAISHA TOSHIBA, Tokyo (JP)

(21) Appl. No.: 19/242,037

(22) Filed: Jun. 18, 2025

(30) Foreign Application Priority Data
Oct. 2, 2024 (JP) 2024-173397

(51) Int. Cl. H10D 30/47; H10D 62/85

(52) U.S. Cl. CPC H10D 30/476; H10D 30/475; H10D 62/8503

(57) ABSTRACT

According to one embodiment, a semiconductor device includes first to third electrodes, a semiconductor member, and a first insulating member. The semiconductor member includes a first semiconductor region including Alₓ₁Ga₁₋ₓ₁N (0≤x1<1), a second semiconductor region including Alₓ₂Ga₁₋ₓ₂N (0<x2<1, x1<x2), and a third semiconductor region including Alₓ₃Ga₁₋ₓ₃N (0<x3<1, x1<x3). The first semiconductor region includes first and semiconductor portions. The second semiconductor region includes third and fourth semiconductor portions. The first insulating member includes first to third insulating regions. At least a part of the second insulating region is between the first semiconductor portion and the first electrode portion of the third electrode. At least a part of the first insulating region is between the fourth partial region and the fifth partial region in the first direction.

### CROSS-REFERENCE TO RELATED APPLICATIONS

This application is based upon and claims the benefit of priority from Japanese Patent Application No. 2024-173397, filed on Oct. 2, 2024; the entire contents of which are incorporated herein by reference.

### FIELD

Embodiments described herein relate generally to a semiconductor device.

### BACKGROUND

For example, it is desired to improve the characteristics of semiconductor devices.

### BRIEF DESCRIPTION OF THE DRAWINGS

FIG. 1 is a schematic cross-sectional view illustrating a semiconductor device according to an embodiment;

FIG. 2 is a graph illustrating the characteristics of a semiconductor device;

FIG. 3 is a graph illustrating the characteristics of a semiconductor device;

FIG. 4 is a schematic cross-sectional view illustrating a semiconductor device according to the embodiment;

FIG. 5 is a schematic cross-sectional view illustrating a semiconductor device according to a third embodiment; and

FIG. 6 is a schematic cross-sectional view illustrating a semiconductor device according to a fourth embodiment.

### DETAILED DESCRIPTION

According to one embodiment, a semiconductor device includes a first electrode, a second electrode, a third electrode including a first electrode portion, a semiconductor member, and a first insulating member. A third electrode position of the first electrode portion in a first direction from the first electrode to the second electrode is between a first electrode position of the first electrode in the first direction and a second electrode position of the second electrode in the first direction. The semiconductor member includes a first semiconductor region including Alₓ₁Ga₁₋ₓ₁N (0≤x1<1), a second semiconductor region including Alₓ₂Ga₁₋ₓ₂N (0<x2<1, x1<x2), and a third semiconductor region including Alₓ₃Ga₁₋ₓ₃N (0<x3<1, x1<x3). The third semiconductor region includes a first partial region, a second partial region, a third partial region, a fourth partial region, and a fifth partial region. A direction from the first partial region to the first electrode is along a second direction crossing the first direction. A direction from the second partial region to the second electrode is along the second direction. The direction from the third partial region to the first electrode portion is along the second direction. A position of the fourth partial region in the first direction is between a position of the first partial region in the first direction and a position of the third partial region in the first direction. A position of the fifth partial region in the first direction is between the position of the third partial region in the first direction and a position of the second partial region in the first direction. The first semiconductor region includes a first semiconductor portion and a second semiconductor portion. The second semiconductor region includes a third semiconductor portion and a fourth semiconductor portion. The first semiconductor portion is between the fourth partial region and the third semiconductor portion in the second direction. The second semiconductor portion is between the fifth partial region and the fourth semiconductor portion in the second direction. The first electrode portion is between the first semiconductor portion and the second semiconductor portion, and between the third semiconductor portion and the fourth semiconductor portion. The first insulating member includes a first insulating region, a second insulating region, and a third insulating region. At least a part of the second insulating region is between the first semiconductor portion and the first electrode portion. At least a part of the third insulating region is between the first electrode portion and the second semiconductor portion. The first insulating region is between the third partial region and the first electrode portion in the second direction. At least a part of the first insulating region is between the fourth partial region and the fifth partial region in the first direction.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

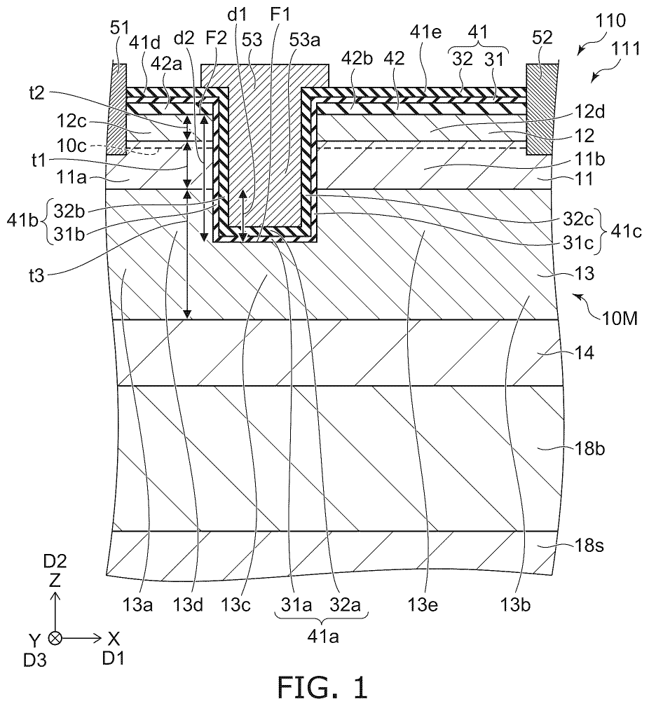

FIG. 1 is a schematic cross-sectional view illustrating a semiconductor device according to a first embodiment.

As shown in FIG. 1, a semiconductor device 110 according to the embodiment includes a first electrode 51, a second electrode 52, a third electrode 53, a semiconductor member 10M, and a first insulating member 41.

A first direction D1 from the first electrode 51 to the second electrode 52 is defined as an X-axis direction. One direction perpendicular to the X-axis direction is defined as a Z-axis direction. A direction perpendicular to the X-axis and Z-axis directions is defined as a Y-axis direction.

The first electrode 51, the second electrode 52, and the third electrode 53 may extend, for example, along a third direction D3. The third direction D3 crosses a plane including the first direction D1 and the second direction D2. The third direction D3 is, for example, the Y-axis direction.

The third electrode 53 includes a first electrode portion 53a. A position of the first electrode portion 53a in the first direction D1 (third electrode position) is between a position of the first electrode 51 in the first direction D1 (first electrode position) and a position of the second electrode 52 in the first direction D1 (second electrode position). For example, at least a part of the first electrode portion 53a may be between the first electrode 51 and the second electrode 52 in the first direction D1.

The semiconductor member 10M includes a first semiconductor region 11, a second semiconductor region 12, and a third semiconductor region 13. The first semiconductor region 11 includes Alₓ₁Ga₁₋ₓ₁N (0≤x1<1). The composition ratio x1 may be, for example, not less than 0 and not more than 0.05. The first semiconductor region 11 may include, for example, GaN (i-GaN).

The second semiconductor region 12 includes Alₓ₂Ga₁₋ₓ₂N (0<x2<1, x1<x2). The composition ratio x2 may be, for example, not less than 0.15 and not more than 0.3. The second semiconductor region 12 includes, for example, AlGaN.

The third semiconductor region 13 includes Alₓ₃Ga₁₋ₓ₃N (0<x3<1, x1<x3). The composition ratio x3 may be, for example, higher than 0.05 and not more than 0.3. The third semiconductor region 13 includes, for example, AlGaN. The third semiconductor region 13 may not include In.

In a second direction D2 crossing the first direction D1, the first semiconductor region 11 is between the third semiconductor region 13 and the second semiconductor region 12. The second direction D2 is, for example, the Z-axis direction.

The third semiconductor region 13 includes a first partial region 13a, a second partial region 13b, a third partial region 13c, a fourth partial region 13d, and a fifth partial region 13e. A direction from the first partial region 13a to the first electrode 51 is along the second direction D2 crossing the first direction D1. A direction from the second partial region 13b to the second electrode 52 is along the second direction D2. A direction from the third partial region 13c to the first electrode portion 53a is along the second direction D2.

The region overlapping the first electrode 51 in the second direction D2 corresponds to the first partial region 13a. The region overlapping the second electrode 52 in the second direction D2 corresponds to the second partial region 13b. The region overlapping the first electrode portion 53a in the second direction D2 corresponds to the third partial region 13c.

A position of the fourth partial region 13d in the first direction D1 is between a position of the first partial region 13a in the first direction D1 and a position of the third partial region 13c in the first direction D1. A position of the fifth partial region 13e in the first direction D1 is between the position of the third partial region 13c in the first direction D1 and a position of the second partial region 13b in the first direction D1. The boundaries between the first partial region 13a, the second partial region 13b, the third partial region 13c, the fourth partial region 13d, and the fifth partial region 13e may be clear or unclear.

The first semiconductor region 11 includes a first semiconductor portion 11a and a second semiconductor portion 11b. The second semiconductor region 12 includes a third semiconductor portion 12c and a fourth semiconductor portion 12d. The first semiconductor portion 11a is between the fourth partial region 13d and the third semiconductor portion 12c in the second direction D2. The second semiconductor portion 11b is between the fifth partial region 13e and the fourth semiconductor portion 12d in the second direction D2.

The first electrode portion 53a is between the first semiconductor portion 11a and the second semiconductor portion 11b, and between the third semiconductor portion 12c and the fourth semiconductor portion 12d.

The first insulating member 41 includes a first insulating region 41a, a second insulating region 41b, and a third insulating region 41c. At least a part of the second insulating region 41b is between the first semiconductor portion 11a and the first electrode portion 53a. A part of the second insulating region 41b may be provided between the third semiconductor portion 12c and the first electrode portion 53a.

At least a part of the third insulating region 41c is between the first electrode portion 53a and the second semiconductor portion 11b. A part of the third insulating region 41c may be provided between the first electrode portion 53a and the fourth semiconductor portion 12d.

The first insulating region 41a is between the third partial region 13c and the first electrode portion 53a in the second direction D2. At least a part of the first insulating region 41a is between the fourth partial region 13d and the fifth partial region 13e in the first direction D1.

For example, the first electrode 51 is electrically connected to the first semiconductor portion 11a. The second electrode 52 is electrically connected to the second semiconductor portion 11b.

For example, current flowing between the first electrode 51 and the second electrode 52 can be controlled by a potential of the third electrode 53. The potential of the third electrode 53 is, for example, a potential based on a potential of the first electrode 51. The first electrode 51 is, for example, a source electrode. The second electrode 52 is, for example, a drain electrode. The third electrode 53 is, for example, a gate electrode. The semiconductor device 110 is, for example, a transistor.

The first semiconductor region 11 includes a region facing the second semiconductor region 12. For example, a carrier region 10c is formed in this region. The carrier region 10c is, for example, a two-dimensional electron gas. The semiconductor device 110 is, for example, a HEMT (High Electron Mobility Transistor).

A distance along the first direction D1 between the first electrode 51 and the third electrode 53 is shorter than a distance along the first direction D1 between the third electrode 53 and the second electrode 52. Stable operation is easily achieved.

As described above, a part of the first insulating member 41 is provided between two partial regions of the third semiconductor region 13. For example, a recess is provided in the semiconductor member 10M, and the first insulating member 41 and the first electrode portion 53a are provided inside the recess. The third electrode 53 is, for example, a recessed gate electrode. For example, a high threshold voltage is easily obtained. For example, a stable normally-off operation is easily obtained.

In the embodiment, the third semiconductor region 13 being above-mentioned is provided. Thereby, it becomes easier to obtain a higher threshold voltage compared to a first reference example in which the third semiconductor region 13 is not provided.

On the other hand, a second reference example is conceivable in which the third semiconductor region 13 is provided and the recess does not reach the inside of the third semiconductor region 13. In the second reference example, the first insulating region 41a is not provided between the two regions of the third semiconductor region 13 in the first direction D1.

On the other hand, as described above, in the embodiment, the first insulating region 41a is provided between two regions (the fourth partial region 13d and the fifth partial region 13e) of the third semiconductor region 13 in the first direction D1. In such a configuration, leakage current can be suppressed. The leakage current is, for example, a current that flows between the drain and source in the off state. In the off state, the gate voltage may be, for example, 0 V. For example, the leakage current in the embodiment can be made 0.1 times or less the leakage current in the second reference example.

According to the embodiment, the leakage current can be reduced. For example, a high threshold voltage can be obtained. According to the embodiment, a semiconductor device with improved characteristics can be provided.

In the embodiment, for example, in a current path including the first semiconductor portion 11a, current is less likely to flow in the recessed part of the third semiconductor region 13. This is thought to suppress the leakage current. This is thought to be due to the effect of the potential barrier at the interface between the third semiconductor region 13 and the first semiconductor region 11.

In the example shown in FIG. 1, a part of the first electrode portion 53a is between the fourth partial region 13d and the fifth partial region 13e in the first direction D1. A high threshold voltage can be obtained more stably.

As shown in FIG. 1, the first semiconductor region 11 may be in contact with the third semiconductor region 13. The second semiconductor region 12 may be in contact with the first semiconductor region 11.

As shown in FIG. 1, a thickness of the first semiconductor region 11 in the second direction D2 is defined as a first thickness t1. A thickness of the second semiconductor region 12 in the second direction D2 is defined as a second thickness t2. A thickness of the third semiconductor region 13 along the second direction D2 is defined as a third thickness t3. The first thickness t1 may be thicker than the second thickness t2. The third thickness t3 may be thicker than the second thickness t2.

The first thickness t1 may be, for example, not less than 60 nm and not more than 300 nm. The first thickness t1 may be, for example, not less than 100 nm and not more than 300 nm. The second thickness t2 may be, for example, not less than 10 nm and not more than 50 nm. The third thickness t3 may be, for example, not less than 300 nm and not more than 1000 nm.

As shown in FIG. 1, the semiconductor member 10M may further include a fourth semiconductor region 14. The fourth semiconductor region 14 includes Alₓ₄Ga₁₋ₓ₄N (0≤x4<1, x4<x3). The composition ratio x4 may be, for example, not less than 0 and not more than 0.1. The fourth semiconductor region 14 includes, for example, GaN. The third semiconductor region 13 is between the fourth semiconductor region 14 and the second semiconductor region 12. The third semiconductor region 13 is between the fourth semiconductor region 14 and the first semiconductor region 11.

A carbon concentration (fourth concentration) in the fourth semiconductor region 14 is higher than a carbon concentration (first concentration) in the first semiconductor region 11. Alternatively, the fourth semiconductor region 14 includes carbon, and the first semiconductor region 11 does not include carbon. The fourth semiconductor region 14 may include GaN including carbon. The fourth semiconductor region 14 makes it easier to obtain, for example, a good electrical breakdown voltage.

In the embodiment, the recess in which the third electrode 53 is provided does not reach the fourth semiconductor region 14. A third partial region 13c is provided between the first electrode portion 53a of the third electrode 53 and the fourth semiconductor region 14. This makes it easier to suppress current collapse.

As shown in FIG. 1, the semiconductor device 110 may include a base 18s. The semiconductor member 10M is provided between the base 18s and the above-mentioned electrode. The base 18s may include, for example, a silicon substrate. The semiconductor member 10M may include a nitride layer 18b. The nitride layer 18b is provided between the base 18s and the fourth semiconductor region 14. The nitride layer 18b may include, for example, Al, Ga, and N.

As shown in FIG. 1, the first insulating member 41 may include a first compound layer 31 and a second compound layer 32. At least a part of the first compound layer 31 is between the second compound layer 32 and the semiconductor member 10M. The first compound layer 31 includes, for example, Al_{z1}Ga_{1-z1}N (x3<z1≤1). The composition ratio z1 may be, for example, not less than 0.6 and not more than 1. The first compound layer 31 may include, for example, AlN.

The second compound layer 32 includes a first element and a second element. The first element includes at least one of Si or Al. The second element includes at least one of oxygen or nitrogen. The second compound layer 32 may include silicon oxide.

The first compound layer 31 may include, for example, a first compound region 31a, a second compound region 31b, and a third compound region 31c. The second compound layer 32 may include, for example, a first compound portion 32a, a second compound portion 32b, and a third compound portion 32c.

The first insulating region 41a includes a first compound region 31a and a first compound portion 32a. The second insulating region 41b includes a second compound region 31b and a second compound portion 32b. The third insulating region 41c includes a third compound region 31c and a third compound portion 32c.

The semiconductor device 110 may further include a second insulating member 42. The second insulating member 42 includes a first insulating portion 42a and a second insulating portion 42b. The first insulating member 41 may further include a fourth insulating region 41d and a fifth insulating region 41e. The first insulating portion 42a is between the third semiconductor portion 12c and the fourth insulating region 41d in the second direction D2. The second insulating portion 42b is between the fourth semiconductor portion 12d and the fifth insulating region 41e in the second direction D2.

The second insulating member 42 may include at least one selected from the group consisting of silicon nitride, silicon oxide, and silicon oxynitride.

In the embodiment, the composition ratio x3 may be lower than the composition ratio x2. Thereby, the stress in the region of the first semiconductor region 11 facing the third semiconductor region 13 becomes greater than the stress in the region of the first semiconductor region 11 facing the second semiconductor region 12. For example, the generation of hole carriers is effectively suppressed.

A ratio of the composition ratio x3 to the composition ratio x2 may be, for example, not less than 0.1 and not more than 0.5. The absolute value of the difference between composition ratio x3 and composition ratio x1 may be not less than 0.05 and not more than 0.15. The absolute value of the difference between composition ratio x3 and composition ratio x1 may be not less than 0.05 and not more than 0.1.

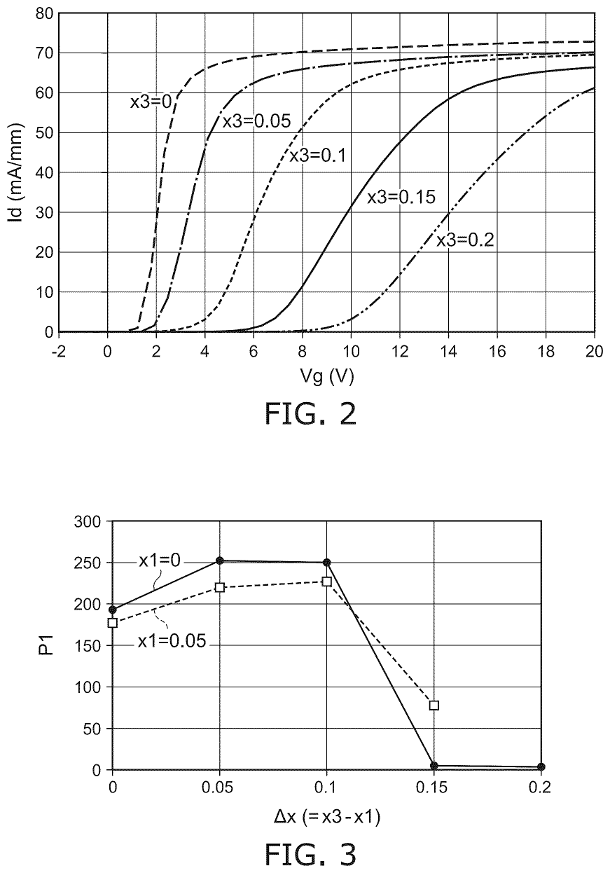

FIG. 2 is a graph illustrating the characteristics of a semiconductor device.

FIG. 2 illustrates the results of a simulation of the characteristics when the composition ratio x3 is changed. The horizontal axis of FIG. 2 is the gate voltage Vg. The vertical axis of FIG. 2 is the drain current Id. As shown in FIG. 2, as the composition ratio x3 increases, the threshold voltage increases.

FIG. 3 is a graph illustrating the characteristics of a semiconductor device.

The horizontal axis of FIG. 3 is the difference Δx between the composition ratio x3 and the composition ratio x1. The composition ratio x3 is higher than composition ratio x1. The vertical axis of FIG. 3 is a first parameter P1. The first parameter P1 corresponds to a ratio of the threshold voltage to the threshold current. The first parameter P1 is normalized by the ratio of the gate voltage in the on state to the on current. In this example, the threshold current is 0.05 mA/mm. The gate voltage in the on state is 8 V. It is preferable that the first parameter P1 is high. When the first parameter P1 is high, a high threshold is obtained. FIG. 3 shows the characteristics in a case where the composition ratio x1 is 0 and the characteristics in a case where the composition ratio x1 is 0.05.

As shown in FIG. 3, the first parameter being high is obtained when the difference Δx in composition ratio is not less than 0.05 and not more than 0.1. In a case where at least the composition ratio x1 is not less than 0 and not more than 0.05, it is preferable that the difference Δx is not less than 0.05 and not more than 0.1.

As shown in FIG. 1, the first insulating region 41a includes a first face F1. The first face F1 faces the third partial region 13c in the second direction D2. The first face F1 corresponds to, for example, the bottom face of the recess. A distance along the second direction D2 between a position in the second direction D2 of the boundary between the third semiconductor region 13 and the first semiconductor region 11 and a position in the second direction D2 of the first face F1 is defined as a first distance d1. The first distance d1 may be, for example, not less than 10 nm and not more than 150 nm. The first distance d1 may be, for example, 50 nm or more. In such a first distance d1, for example, the effect of the potential barrier at the interface between the third semiconductor region 13 and the first semiconductor region 11 is effectively acted upon. For example, a high threshold voltage is stably obtained.

The third semiconductor portion 12c includes a second face F2. The second face F2 faces the first insulating portion 42a. A distance along the second direction D2 between a position of the second face F2 in the second direction D2 and a position of the first face F1 in the second direction D2 is defined as a second distance d2. The second distance d2 corresponds to, for example, the depth of the recess. The second distance d2 may be, for example, not less than 150 nm and not more than 300. For example, an appropriate threshold voltage is easily obtained.

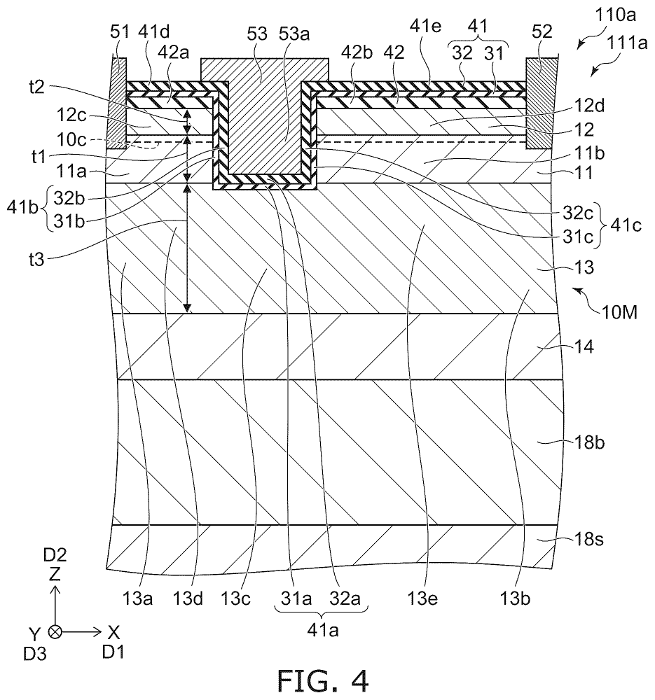

FIG. 4 is a schematic cross-sectional view illustrating a semiconductor device according to the embodiment.

As shown in FIG. 4, in a semiconductor device 110a according to the embodiment, the configuration of the first electrode portion 53a is different from that in the semiconductor device 110. Except for this, the configuration of the semiconductor device 110a may be the same as the configuration of the semiconductor device 110.

In the semiconductor device 110a as well, at least a part of the first insulating region 41a is between the fourth partial region 13d and the fifth partial region 13e in the first direction D1. The first electrode portion 53a does not include a portion between the fourth partial region 13d and the fifth partial region 13e in the first direction D1. In such a semiconductor device 110a as well, leakage current is suppressed. A high threshold value is obtained. Characteristics can be improved.

In the first embodiment, the third semiconductor region 13 does not need to include substantially Mg. Thereby, it becomes easier to obtain high crystallinity. It also makes it easier to obtain a lower on-resistance. In a case where the third semiconductor region 13 includes Al, the Mg concentration in the third semiconductor region 13 may be less than 1×10¹⁷ cm⁻³.

### Second Embodiment

FIGS. 1 and 4 also illustrate the configuration of a semiconductor device according to the second embodiment. As shown in FIG. 1, a semiconductor device 111 according to the embodiment also includes a first electrode 51, a second electrode 52, a third electrode 53, a semiconductor member 10M, and a first insulating member 41. The semiconductor member 10M includes a first semiconductor region 11, a second semiconductor region 12, and a third semiconductor region 13. In the semiconductor device 111, the material of the third semiconductor region 13 is different from that in the semiconductor device 110. Except for this, the configuration of the semiconductor device 111 may be the same as the configuration of the semiconductor device 110.

In the semiconductor device 111, the third semiconductor region 13 includes Alₓ₃Ga₁₋ₓ₃N (0≤x3<1). The composition ratio x3 may be, for example, not less than 0 and not more than 0.1. The third semiconductor region 13 includes Mg. The third semiconductor region 13 may be, for example, p-type GaN.

In the semiconductor device 111, the first insulating region 41a is also located between the third partial region 13c and the first electrode portion 53a in the second direction D2. At least a part of the first insulating region 41a is located between the fourth partial region 13d and the fifth partial region 13e in the first direction D1. In the semiconductor device 111, leakage current can be suppressed. A high threshold voltage can be obtained. Characteristics can be improved.

In the semiconductor device 111, the semiconductor member 10M may further include a fourth semiconductor region 14 including Alₓ₄Ga₁₋ₓ₄N (0≤x4<1, x4<x3). The third semiconductor region 13 is between the fourth semiconductor region 14 and the second semiconductor region 12. The third semiconductor region 13 is between the fourth semiconductor region 14 and the first semiconductor region 11. The fourth concentration of carbon in the fourth semiconductor region 14 is higher than the first concentration of carbon in the first semiconductor region 11. Alternatively, the fourth semiconductor region 14 includes carbon, and the first semiconductor region 11 does not include carbon.

In the semiconductor device 111, the first insulating member 41 may include a first compound layer 31 and a second compound layer 32. At least a part of the first compound layer 31 is between the second compound layer 32 and the semiconductor member 10M. The first compound layer 31 includes Al_{z1}Ga_{1-z1}N (x3<z1≤1). The second compound layer 32 includes a first element and a second element. The first element includes at least one of Si or Al. The second element includes at least one of oxygen or nitrogen.

The semiconductor device 111 may include a second insulating member 42. The second insulating member 42 includes a first insulating portion 42a and a second insulating portion 42b. The first insulating member 41 includes a fourth insulating region 41d and a fifth insulating region 41e. The first insulating portion 42a is between the third semiconductor portion 12c and the fourth insulating region 41d in the second direction D2. The second insulating portion 42b is between the fourth semiconductor portion 12d and the fifth insulating region 41e in the second direction D2.

In the example of FIG. 1, a part of the first electrode portion 53a is located between the fourth partial region 13d and the fifth partial region 13e in the first direction D1.

As shown in FIG. 4, in a semiconductor device 111a according to the embodiment, the configuration of the first electrode portion 53a is different from that in the semiconductor device 111. Except for this, the configuration of the semiconductor device 111a may be the same as the configuration of the semiconductor device 111. In the semiconductor device 111a, the third semiconductor region 13 includes Mg.

In the semiconductor device 111a as well, at least a part of the first insulating region 41a is between the fourth partial region 13d and the fifth partial region 13e in the first direction D1. The first electrode portion 53a does not include a portion between the fourth partial region 13d and the fifth partial region 13e in the first direction D1. In such a semiconductor device 111a as well, leakage current is suppressed. A high threshold value is obtained. Characteristics can be improved.

### Third Embodiment

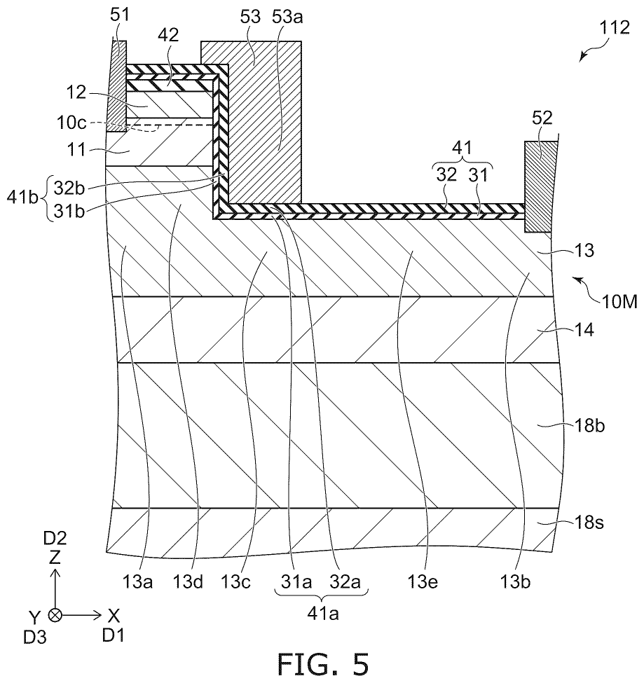

FIG. 5 is a schematic cross-sectional view illustrating a semiconductor device according to a third embodiment.

As shown in FIG. 5, a semiconductor device 112 according to the embodiment includes a first electrode 51, a second electrode 52, a third electrode 53, a semiconductor member 10M, and a first insulating member 41.

The position (third electrode position) of the third electrode 53 in the first direction D1 from the first electrode 51 to the second electrode 52 is between the position (first electrode position) of the first electrode 51 in the first direction D1 and the position (second electrode position) of the second electrode 52 in the first direction D1.

The semiconductor member 10M includes a first semiconductor region 11 including Alₓ₁Ga₁₋ₓ₁N (0≤x1<1), a second semiconductor region 12 including Alₓ₂Gₐ₁₋ₓ₂N (0<x2<1, x1<x2), and the third semiconductor region 13 including Alₓ₃Ga₁₋ₓ₃N (0<x3<1, x1<x3).

The third semiconductor region 13 includes a first partial region 13a, a second partial region 13b, a third partial region 13c, a fourth partial region 13d, and a fifth partial region 13e. The direction from the first partial region 13a to the first electrode 51 is along the second direction D2 crossing the first direction D1. The direction from the second partial region 13b to the second electrode 52 is along the second direction D2. The direction from the third partial region 13c to the third electrode 53 is along the second direction D2. The position of the fourth partial region 13d in the first direction D1 is between the position of the first partial region 13a in the first direction D1 and the position of the third partial region 13c in the first direction D1. The position of the fifth partial region 13e in the first direction D1 is between the position of the third partial region 13c in the first direction D1 and the position of the second partial region 13b in the first direction D1.

In the second direction D2, the first semiconductor region 11 is between the fourth partial region 13d and the second semiconductor region 12.

The first insulating member 41 includes a first insulating region 41a and a second insulating region 41b. The first insulating region 41a is between the third partial region 13c and the third electrode 53 in the second direction D2. The first insulating region 41a is between the fourth partial region 13d and the second electrode 52 in the first direction D1.

At least a part of the second insulating region 41b is located between the first semiconductor region 11 and the third electrode 53, and between the second semiconductor region 12 and the third electrode 53, in the first direction D1. The first electrode 51 is connected to the first semiconductor region 11. The second electrode 52 is connected to the second partial region 13b.

In the semiconductor device 112 as well, the current flowing between the first electrode 51 and the second electrode 52 can be controlled by the potential of the third electrode 53. The fourth partial region 13d of the third semiconductor region 13 faces the first insulating region 41a in the first direction D1. In the semiconductor device 112 as well, the leakage current can be suppressed. A high threshold voltage can be obtained. Characteristics can be improved.

In the example of FIG. 5, a part of the third electrode 53 is between the fourth partial region 13d and the second electrode 52 in the first direction D1. A more stable and high threshold voltage can be obtained. The leakage current can be further reduced.

In the semiconductor device 112, the absolute value of the difference between the composition ratio x3 and the composition ratio x1 may be, for example, not less than 0.05 and not more than 0.1. The ratio of the composition ratio x3 to the composition ratio x2 may be, for example, not less than 0.1 and not more than 0.5.

In the semiconductor device 112, the first insulating member 41 may also include a first compound layer 31 and a second compound layer 32. At least a part of the first compound layer 31 is between the second compound layer 32 and the semiconductor member 10M. The first compound layer 31 includes, for example, Al_{z1}G_{a1-z1}N (x3<z1≤1). The second compound layer 32 includes a first element and a second element. The first element includes at least one of Si or Al. The second element includes at least one of oxygen or nitrogen.

### Fourth Embodiment

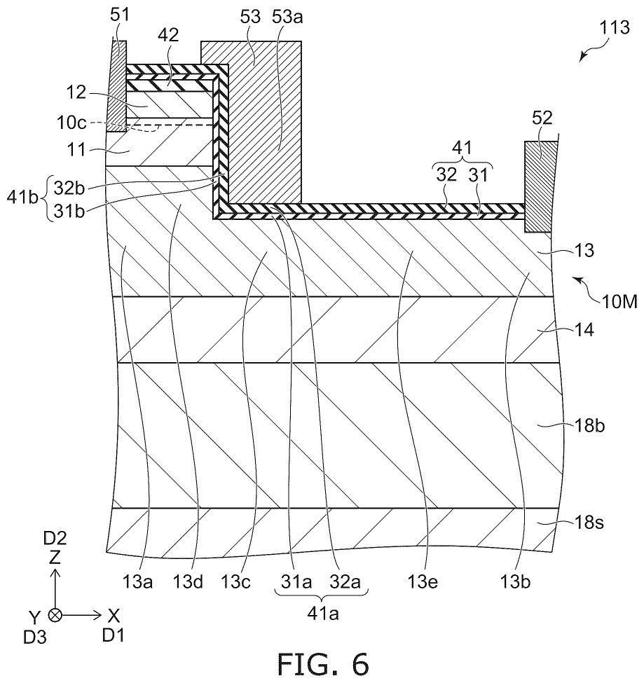

FIG. 6 is a schematic cross-sectional view illustrating a semiconductor device according to a fourth embodiment.

As shown in FIG. 6, in a semiconductor device 113 according to the embodiment, the first electrode 51, the second electrode 52, the third electrode 53, the semiconductor member 10M, and the first insulating member 41 are provided. The semiconductor member 10M includes the first semiconductor region 11, the second semiconductor region 12, and the third semiconductor region 13. In the semiconductor device 113, the material of the third semiconductor region 13 is different from that in the semiconductor device 112. Except for this, the configuration of the semiconductor device 113 may be the same as the configuration of the semiconductor device 112.

In the semiconductor device 113, the third semiconductor region 13 includes Alₓ₃Ga₁₋ₓ₃N (0≤x3<1). The composition ratio x3 may be, for example, not less than 0 and not more than 0.1. The third semiconductor region 13 includes Mg. The third semiconductor region 13 may be, for example, p-type GaN. In the semiconductor device 113, leakage current can be suppressed. A high threshold voltage can be obtained. Characteristics can be improved.

In the embodiment, information regarding the shapes of the semiconductor regions and the electrodes is obtained, for example, from electron microscope images. Information regarding the composition and element concentrations is obtained, for example, from EDX (Energy Dispersive X-ray Spectroscopy) or SIMS (Secondary Ion Mass Spectrometry). Information regarding the composition may be obtained, for example, from reciprocal space mapping.

The embodiment may include the following Technical proposals:

### Technical Proposal 1

A semiconductor device, comprising:
a first electrode:
a second electrode;
a third electrode including a first electrode portion, a third electrode position of the first electrode portion in a first direction from the first electrode to the second electrode being between a first electrode position of the first electrode in the first direction and a second electrode position of the second electrode in the first direction;
a semiconductor member; and
a first insulating member,
the semiconductor member including
   a first semiconductor region including Alₓ₁Ga₁₋ₓ₁N (0≤x1<1),
   a second semiconductor region including Alₓ₂Ga₁₋ₓ₂N (0<x2<1, x1<x2), and
   a third semiconductor region including Alₓ₃Ga₁₋ₓ₃N (0<x3<1, x1<x3),
the third semiconductor region including a first partial region, a second partial region, a third partial region, a fourth partial region, and a fifth partial region,
a direction from the first partial region to the first electrode being along a second direction crossing the first direction,
a direction from the second partial region to the second electrode being along the second direction,
a direction from the third partial region to the first electrode portion being along the second direction,
a position of the fourth partial region in the first direction being between a position of the first partial region in the first direction and a position of the third partial region in the first direction,
a position of the fifth partial region in the first direction being between the position of the third partial region in the first direction and a position of the second partial region in the first direction,
the first semiconductor region including a first semiconductor portion and a second semiconductor portion,
the second semiconductor region including a third semiconductor portion and a fourth semiconductor portion,
the first semiconductor portion being between the fourth partial region and the third semiconductor portion in the second direction,
the second semiconductor portion being between the fifth partial region and the fourth semiconductor portion in the second direction,
the first electrode portion being between the first semiconductor portion and the second semiconductor portion, and between the third semiconductor portion and the fourth semiconductor portion,
the first insulating member including a first insulating region, a second insulating region, and a third insulating region,
at least a part of the second insulating region being between the first semiconductor portion and the first electrode
portion, at least a part of the third insulating region being between
the first electrode portion and the second semiconductor portion, the first insulating region being between the third partial region and the first electrode portion in the second direction, and
at least a part of the first insulating region being between the fourth partial region and the fifth partial region in the first direction.

### Technical Proposal 2

The semiconductor device according to Technical proposal 1, wherein
a part of the first electrode portion is between the fourth partial region and the fifth partial region in the first direction.

### Technical Proposal 3

The semiconductor device according to Technical proposal 1 or 2, wherein
the first semiconductor region is in contact with the third semiconductor region, and
the second semiconductor region is in contact with the first semiconductor region.

### Technical Proposal 4

The semiconductor device according to any one of Technical proposals 1-3, wherein
the x3 is lower than the x2.

### Technical Proposal 5

The semiconductor device according to any one of Technical proposals 1-3, wherein
a ratio of the x3 to the x2 is not less than 0.1 and not more than 0.5.

### Technical Proposal 6

The semiconductor device according to any one of Technical proposals 1-5, wherein
an absolute value of a difference between the x3 and the x1 is not less than 0.05 and not more than 0.1.

### Technical Proposal 7

The semiconductor device according to any one of Technical proposals 1-6, wherein
a third thickness of the third semiconductor region along the second direction is greater than a second thickness of the second semiconductor region along the second direction.

### Technical Proposal 8

The semiconductor device according to any one of Technical proposals 1-7, wherein
the first electrode is electrically connected to the first semiconductor portion, and
the second electrode is electrically connected to the second semiconductor portion.

### Technical Proposal 9

The semiconductor device according to any one of Technical proposals 1-8, wherein
the semiconductor member further includes a fourth semiconductor region including Alₓ₄Ga₁₋ₓ₄N (0≤x4<1, x4<x3),
the third semiconductor region is between the fourth semiconductor region and the second semiconductor region,
the third semiconductor region is between the fourth semiconductor region and the first semiconductor region,
a fourth concentration of carbon in the fourth semiconductor region is higher than a first concentration of carbon in the first semiconductor region, or
the fourth semiconductor region includes carbon and the first semiconductor region does not include carbon.

### Technical Proposal 10

The semiconductor device according to any one of Technical proposals 1-9, wherein
the first insulating member includes a first compound layer and a second compound layer,
at least a part of the first compound layer is between the second compound layer and the semiconductor member,
the first compound layer includes Al_{z1}Ga_{1-z1}N (x3<z1≤1), and
the second compound layer includes a first element and a second element, the first element includes at least one of Si or Al,
and the second element includes at least one of oxygen or nitrogen.

### Technical Proposal 11

The semiconductor device according to any one of Technical proposals 1-10, further comprising:
a second insulating member including a first insulating portion and a second insulating portion,
the first insulating member further including a fourth insulating region and a fifth insulating region,
the first insulating portion being between the third semiconductor portion and the fourth insulating region in the second direction, and
the second insulating portion being between the fourth semiconductor portion and the fifth insulating region in the second direction.

### Technical Proposal 12

A semiconductor device, comprising:
a first electrode:
a second electrode;
a third electrode including a first electrode portion, a third electrode position of the first electrode portion in a first direction from the first electrode to the second electrode being between a first electrode position of the first electrode in the first direction and a second electrode position of the second electrode in the first direction;
a semiconductor member; and
a first insulating member,
the semiconductor member including
   a first semiconductor region including Alₓ₁Ga₁₋ₓ₁N (0≤x1<1),
   a second semiconductor region including Alₓ₂Ga₁₋ₓ₂N (0<x2<1, x1<x2), and
   a third semiconductor region including Alₓ₃Ga₁₋ₓ₃N (0<x3<1, x1<x3),
the third semiconductor region including Mg,
the third semiconductor region including a first partial region, a second partial region, a third partial region, a fourth partial region, and a fifth partial region,
a direction from the first partial region to the first electrode being along a second direction crossing the first direction,
a direction from the second partial region to the second electrode being along the second direction,
a direction from the third partial region to the first electrode being along the second direction,
a position of the fourth partial region in the first direction being between a position of the first partial region in the first direction and a position of the third partial region in the first direction,
a position of the fifth partial region in the first direction being between the position of the third partial region in the first direction and a position of the second partial region in the first direction,
the first semiconductor region including a first semiconductor portion and a second semiconductor portion,
the second semiconductor region including a third semiconductor portion and a fourth semiconductor portion,
the first semiconductor portion being between the fourth partial region and the third semiconductor portion in the second direction,
the second semiconductor portion being between the fifth partial region and the fourth semiconductor portion in the second direction,
the first electrode portion being between the first semiconductor portion and the second semiconductor portion, and between the third semiconductor portion and the fourth semiconductor portion,
the first insulating member including a first insulating region, a second insulating region, and a third insulating region,
at least a part of the second insulating region being between the first semiconductor portion and the first electrode portion,
at least a part of the third insulating region being between the first electrode portion and the second semiconductor portion,
the first insulating region being between the third partial region and the first electrode portion in the second direction, and
at least a part of the first insulating region being between the fourth partial region and the fifth partial region in the first direction.

### Technical Proposal 13

The semiconductor device according to Technical proposal 12, wherein
a part of the first electrode portion is between the fourth partial region and the fifth partial region in the first direction.

### Technical Proposal 14

The semiconductor device according to Technical proposal 12 or 13, wherein
the semiconductor member further includes a fourth semiconductor region including Alₓ₄Ga₁₋ₓ₄N (0≤x4<1, x4<x3),
the third semiconductor region is between the fourth semiconductor region and the second semiconductor region,
the third semiconductor region is between the fourth semiconductor region and the first semiconductor region,
a fourth concentration of carbon in the fourth semiconductor region is higher than a first concentration of carbon in the first semiconductor region, or
the fourth semiconductor region includes carbon and the first semiconductor region does not include carbon.

### Technical Proposal 15

The semiconductor device according to any one of Technical proposals 12-14, wherein
the first insulating member includes a first compound layer and a second compound layer,
at least a part of the first compound layer is between the second compound layer and the semiconductor member,
the first compound layer includes Al_{z1}Ga_{1-z1}N (x3<z1≤1), and
the second compound layer includes a first element and a second element, the first element includes at least one of Si or Al, and the second element includes at least one of oxygen or nitrogen.

### Technical Proposal 16

The semiconductor device according to any one of Technical proposals 12-15, further comprising:
a second insulating member including a first insulating portion and a second insulating portion,
the first insulating member further including a fourth insulating region and a fifth insulating region,
the first insulating portion being between the third semiconductor portion and the fourth insulating region in the second direction,
the second insulating portion being between the fourth semiconductor portion and the fifth insulating region in the second direction.

### Technical Proposal 17

A semiconductor device, comprising:
a first electrode:
a second electrode;
a third electrode, a third electrode position of the third electrode in a first direction from the first electrode to the second electrode being between a first electrode position of the first electrode in the first direction and a second electrode position of the second electrode in the first direction;
a semiconductor member; and
a first insulating member,
the semiconductor member including
   a first semiconductor region including Alₓ₁Ga₁₋ₓ₁N (0≤x1<1),
   a second semiconductor region including Alₓ₂Ga₁₋ₓ₂N (0<x2<1, x1<x2), and
   a third semiconductor region including Alₓ₃Ga₁₋ₓ₃N (0<x3<1, x1<x3),
the third semiconductor region including a first partial region, a second partial region, a third partial region, a fourth partial region, and a fifth partial region,
a direction from the first partial region to the first electrode being along a second direction crossing the first direction,
a direction from the second partial region to the second electrode being along the second direction,
a position of the fourth partial region in the first direction being between a position of the first partial region in the first direction and a position of the third partial region in the first direction,
a position of the fifth partial region in the first direction is between the position of the third partial region in the first direction and a position of the second partial region in the first direction,
in the second direction, the first semiconductor region being between the fourth partial region and the second semiconductor region,
the first insulating member including a first insulating region and a second insulating region,
the first insulating region being between the third partial region and the third electrode in the second direction,
the first insulating region being between the fourth partial region and the second electrode in the first direction,
at least a part of the second insulating region being between the first semiconductor region and the third electrode, and between the second semiconductor region and the third electrode in the first direction,
the first electrode being connected to the first semiconductor region,
the second electrode being connected to the second partial region.

### Technical Proposal 18

The semiconductor device according to Technical proposal 17, wherein
a part of the third electrode is between the fourth partial region and the second electrode in the first direction.

### Technical Proposal 19

The semiconductor device according to Technical proposal 17 or 18, wherein
an absolute value of a difference between the x3 and the x1 is not less than 0.05 and not more than 0.1.

### Technical Proposal 20

A semiconductor device, comprising:
a first electrode:
a second electrode;
a third electrode, a third electrode position of the third electrode in a first direction from the first electrode to the second electrode being between a first electrode position of the first electrode in the first direction and a second electrode position of the second electrode in the first direction;
a semiconductor member; and
a first insulating member,
the semiconductor member including
   a first semiconductor region including Alₓ₁Ga₁₋ₓ₁N (0≤x1<1),
   a second semiconductor region including Alₓ₂Ga₁₋ₓ₂N (0<x2<1, x1<x2), and
   a third semiconductor region including Alₓ₃Ga₁₋ₓ₃N (0<x3<1, x1<x3),
the third semiconductor region includes Mg,
the third semiconductor region including a first partial region, a second partial region, a third partial region, a fourth partial region, and a fifth partial region,
a direction from the first partial region to the first electrode being along a second direction crossing the first direction,
a direction from the second partial region to the second electrode being along the second direction,
a direction from the third partial region to the third electrode being along the second direction,
a position of the fourth partial region in the first direction being between a position of the first partial region in the first direction and a position of the third partial region in the first direction,
a position of the fifth partial region in the first direction is between the position of the third partial region in the first direction and a position of the second partial region in the first direction,
in the second direction, the first semiconductor region being between the fourth partial region and the second semiconductor region,
the first insulating member including a first insulating region and a second insulating region,
the first insulating region being between the third partial region and the third electrode in the second direction,
the first insulating region being between the fourth partial region and the second electrode in the first direction,
at least a part of the second insulating region being between the first semiconductor region and the third electrode, and between the second semiconductor region and the third electrode in the first direction,
the first electrode being connected to the first semiconductor region, and
the second electrode being connected to the second partial region.

According to the embodiment, a semiconductor device is provided that can improve characteristics.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor devices such as electrodes, semiconductor members, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode:
a second electrode;
a third electrode including a first electrode portion, a third electrode position of the first electrode portion in a first direction from the first electrode to the second electrode being between a first electrode position of the first electrode in the first direction and a second electrode position of the second electrode in the first direction;
a semiconductor member; and
a first insulating member,
the semiconductor member including
a first semiconductor region including Alₓ₁Ga₁₋ₓ₁N (0≤x1<1),
a second semiconductor region including Alₓ₂Ga₁₋ₓ₂N (0<x2<1, x1<x2), and
a third semiconductor region including Alₓ₃Ga₁₋ₓ₃N (0<x3<1, x1<x3),
the third semiconductor region including a first partial region, a second partial region, a third partial region, a fourth partial region, and a fifth partial region,
a direction from the first partial region to the first electrode being along a second direction crossing the first direction,
a direction from the second partial region to the second electrode being along the second direction,
a direction from the third partial region to the first electrode portion being along the second direction,
a position of the fourth partial region in the first direction being between a position of the first partial region in the first direction and a position of the third partial region in the first direction,
a position of the fifth partial region in the first direction being between the position of the third partial region in the first direction and a position of the second partial region in the first direction,
the first semiconductor region including a first semiconductor portion and a second semiconductor portion,
the second semiconductor region including a third semiconductor portion and a fourth semiconductor portion,
the first semiconductor portion being between the fourth partial region and the third semiconductor portion in the second direction,
the second semiconductor portion being between the fifth partial region and the fourth semiconductor portion in the second direction,
the first electrode portion being between the first semiconductor portion and the second semiconductor portion, and between the third semiconductor portion and the fourth semiconductor portion,
the first insulating member including a first insulating region, a second insulating region, and a third insulating region,
at least a part of the second insulating region being between the first semiconductor portion and the first electrode portion,
at least a part of the third insulating region being between the first electrode portion and the second semiconductor portion,
the first insulating region being between the third partial region and the first electrode portion in the second direction, and
at least a part of the first insulating region being between the fourth partial region and the fifth partial region in the first direction.

2. The semiconductor device according to claim 1, wherein
a part of the first electrode portion is between the fourth partial region and the fifth partial region in the first direction.

3. The semiconductor device according to claim 1, wherein
the first semiconductor region is in contact with the third semiconductor region, and
the second semiconductor region is in contact with the first semiconductor region.

4. The semiconductor device according to claim 1, wherein the x3 is lower than the x2.

5. The semiconductor device according to claim 1, wherein
a ratio of the x3 to the x2 is not less than 0.1 and not more than 0.5.

6. The semiconductor device according to claim 1, wherein
an absolute value of a difference between the x3 and the x1 is not less than 0.05 and not more than 0.1.

7. The semiconductor device according claim 1, wherein
a third thickness of the third semiconductor region along the second direction is greater than a second thickness of the second semiconductor region along the second direction.

8. The semiconductor device according to claim 1, wherein
the first electrode is electrically connected to the first semiconductor portion, and
the second electrode is electrically connected to the second semiconductor portion.

9. The semiconductor device according to claim 1, wherein
the semiconductor member further includes a fourth semiconductor region including Alₓ₄Ga₁₋ₓ₄N (0≤x4<1, x4<x3),
the third semiconductor region is between the fourth semiconductor region and the second semiconductor region,
the third semiconductor region is between the fourth semiconductor region and the first semiconductor region,
a fourth concentration of carbon in the fourth semiconductor region is higher than a first concentration of carbon in the first semiconductor region, or
the fourth semiconductor region includes carbon and the first semiconductor region does not include carbon.

10. The semiconductor device according to claim 1, wherein
the first insulating member includes a first compound layer and a second compound layer,
at least a part of the first compound layer is between the second compound layer and the semiconductor member,
the first compound layer includes Al_{z1}Ga_{1-z1}N (x3<z1≤1), and
the second compound layer includes a first element and a second element, the first element includes at least one of Si or Al, and the second element includes at least one of oxygen or nitrogen.

11. The semiconductor device according to claim 1, further comprising:
a second insulating member including a first insulating portion and a second insulating portion,
the first insulating member further including a fourth insulating region and a fifth insulating region,
the first insulating portion being between the third semiconductor portion and the fourth insulating region in the second direction, and
the second insulating portion being between the fourth semiconductor portion and the fifth insulating region in the second direction.

12. A semiconductor device, comprising:
a first electrode:
a second electrode;
a third electrode including a first electrode portion, a third electrode position of the first electrode portion in a first direction from the first electrode to the second electrode being between a first electrode position of the first electrode in the first direction and a second electrode position of the second electrode in the first direction;
a semiconductor member; and
a first insulating member,
the semiconductor member including
a first semiconductor region including Alₓ₁Ga₁₋ₓ₁N (0≤x1<1),
a second semiconductor region including Alₓ₂Ga₁₋ₓ₂N (0<x2<1, x1<x2), and
a third semiconductor region including Alₓ₃Ga₁₋ₓ₃N (0<x3<1, x1<x3),
the third semiconductor region including Mg,
the third semiconductor region including a first partial region, a second partial region, a third partial region, a fourth partial region, and a fifth partial region,
a direction from the first partial region to the first electrode being along a second direction crossing the first direction,
a direction from the second partial region to the second electrode being along the second direction,
a direction from the third partial region to the first electrode being along the second direction,
a position of the fourth partial region in the first direction being between a position of the first partial region in the first direction and a position of the third partial region in the first direction,
a position of the fifth partial region in the first direction being between the position of the third partial region in the first direction and a position of the second partial region in the first direction,
the first semiconductor region including a first semiconductor portion and a second semiconductor portion,
the second semiconductor region including a third semiconductor portion and a fourth semiconductor portion,
the first semiconductor portion being between the fourth partial region and the third semiconductor portion in the second direction,
the second semiconductor portion being between the fifth partial region and the fourth semiconductor portion in the second direction,
the first electrode portion being between the first semiconductor portion and the second semiconductor portion, and between the third semiconductor portion and the fourth semiconductor portion,
the first insulating member including a first insulating region, a second insulating region, and a third insulating region,
at least a part of the second insulating region being between the first semiconductor portion and the first electrode portion,
at least a part of the third insulating region being between the first electrode portion and the second semiconductor portion,
the first insulating region being between the third partial region and the first electrode portion in the second direction, and
at least a part of the first insulating region being between the fourth partial region and the fifth partial region in the first direction.

13. The semiconductor device according to claim 12, wherein
a part of the first electrode portion is between the fourth partial region and the fifth partial region in the first direction.

14. The semiconductor device according to claim 12, wherein
the semiconductor member further includes a fourth semiconductor region including Alₓ₄Ga₁₋ₓ₄N (0≤x4<1, x4<x3),
the third semiconductor region is between the fourth semiconductor region and the second semiconductor region,
the third semiconductor region is between the fourth semiconductor region and the first semiconductor region,
a fourth concentration of carbon in the fourth semiconductor region is higher than a first concentration of carbon in the first semiconductor region, or
the fourth semiconductor region includes carbon and the first semiconductor region does not include carbon.

15. The semiconductor device according to claim 12, wherein
the first insulating member includes a first compound layer and a second compound layer,
at least a part of the first compound layer is between the second compound layer and the semiconductor member,
the first compound layer includes Al_{z1}Ga_{1-z1}N (x3<z1≤1), and
the second compound layer includes a first element and a second element, the first element includes at least one of Si or Al, and the second element includes at least one of oxygen or nitrogen.

16. The semiconductor device according to claim 12, further comprising:
a second insulating member including a first insulating portion and a second insulating portion,
the first insulating member further including a fourth insulating region and a fifth insulating region,
the first insulating portion being between the third semiconductor portion and the fourth insulating region in the second direction,
the second insulating portion being between the fourth semiconductor portion and the fifth insulating region in the second direction.

17. A semiconductor device, comprising:
a first electrode:
a second electrode;
a third electrode, a third electrode position of the third electrode in a first direction from the first electrode to the second electrode being between a first electrode position of the first electrode in the first direction and a second electrode position of the second electrode in the first direction;
a semiconductor member; and
a first insulating member,
the semiconductor member including
a first semiconductor region including Alₓ₁Ga₁₋ₓ₁N (0≤x1<1),
a second semiconductor region including Alₓ₂Ga₁₋ₓ₂N (0<x2<1, x1<x2), and
a third semiconductor region including Alₓ₃Ga₁₋ₓ₃N (0<x3<1, x1<x3),
the third semiconductor region including a first partial region, a second partial region, a third partial region, a fourth partial region, and a fifth partial region,
a direction from the first partial region to the first electrode being along a second direction crossing the first direction,
a direction from the second partial region to the second electrode being along the second direction,
a position of the fourth partial region in the first direction being between a position of the first partial region in the first direction and a position of the third partial region in the first direction,
a position of the fifth partial region in the first direction is between the position of the third partial region in the first direction and a position of the second partial region in the first direction,
in the second direction, the first semiconductor region being between the fourth partial region and the second semiconductor region,
the first insulating member including a first insulating region and a second insulating region,
the first insulating region being between the third partial region and the third electrode in the second direction,
the first insulating region being between the fourth partial region and the second electrode in the first direction,
at least a part of the second insulating region being between the first semiconductor region and the third electrode, and between the second semiconductor region and the third electrode in the first direction,
the first electrode being connected to the first semiconductor region,
the second electrode being connected to the second partial region.

18. The semiconductor device according to claim 17, wherein
a part of the third electrode is between the fourth partial region and the second electrode in the first direction.

19. The semiconductor device according to claim 17, wherein
an absolute value of a difference between the x3 and the x1 is not less than 0.05 and not more than 0.1.

20. A semiconductor device, comprising:
a first electrode:
a second electrode;
a third electrode, a third electrode position of the third electrode in a first direction from the first electrode to the second electrode being between a first electrode position of the first electrode in the first direction and a second electrode position of the second electrode in the first direction;
a semiconductor member; and
a first insulating member,
the semiconductor member including
a first semiconductor region including Alₓ₁Ga₁₋ₓ₁N (0≤x1<1),
a second semiconductor region including Alₓ₂Ga₁₋ₓ₂N (0<x2<1, x1<x2), and
a third semiconductor region including Alₓ₃Ga₁₋ₓ₃N (0<x3<1, x1<x3),
the third semiconductor region includes Mg,
the third semiconductor region including a first partial region, a second partial region, a third partial region, a fourth partial region, and a fifth partial region,
a direction from the first partial region to the first electrode being along a second direction crossing the first direction,
a direction from the second partial region to the second electrode being along the second direction,
a direction from the third partial region to the third electrode being along the second direction,
a position of the fourth partial region in the first direction being between a position of the first partial region in the first direction and a position of the third partial region in the first direction,
a position of the fifth partial region in the first direction is between the position of the third partial region in the first direction and a position of the second partial region in the first direction,
in the second direction, the first semiconductor region being between the fourth partial region and the second semiconductor region,
the first insulating member including a first insulating region and a second insulating region,
the first insulating region being between the third partial region and the third electrode in the second direction,
the first insulating region being between the fourth partial region and the second electrode in the first direction,
at least a part of the second insulating region being between the first semiconductor region and the third electrode, and between the second semiconductor region and the third electrode in the first direction,
the first electrode being connected to the first semiconductor region, and
the second electrode being connected to the second partial region.
